(19) United States
(12) Patent Application Publication
(10) Pub. No.: US 2019/0157311 A1
(43) Pub. Date: May 23, 2019

(54) FLEXIBLE ARRAY SUBSTRATE AND PREPARATION METHOD THEREOF, DISPLAY SUBSTRATE AND DISPLAY DEVICE

(71) Applicant: BOE TECHNOLOGY GROUP CO., LTD., Beijing (CN)

(72) Inventor: Shuai ZHANG, Beijing (CN)

(21) Appl. No.: 16/138,745

(22) Filed: Sep. 21, 2018

(30) Foreign Application Priority Data
Nov. 20, 2017 (CN) 201711163249.4

(51) Int. Cl. H01L 27/12

(52) U.S. Cl. CPC H01L 27/1218; H01L 27/1248; H01L 27/1262; H01L 27/1244

(57) ABSTRACT

A flexible array substrate includes a display area and a non-display area, and the non-display area includes a bending area adjacent to the display area. The bending area includes a plurality of signal lines and a plurality of auxiliary lines on the base substrate, and the plurality of auxiliary lines are on a side of the plurality of signal lines away from the base substrate. An insulating layer is disposed between the plurality of auxiliary lines and the plurality of signal lines, and the insulating layer is provided with a concave section group formed by a plurality of concave sections which are arranged along an extension direction of the signal line in a region where the bending area overlaps any one of at least some signal lines of the plurality of signal lines, and each of the auxiliary lines covers at least one of concave section groups.

### CROSS-REFERENCE TO RELATED APPLICATION

This application claims priority to Chinese Patent Application No. 201711163249.4, filed on Nov. 20, 2017, titled “FLEXIBLE ARRAY SUBSTRATE AND PREPARATION METHOD THEREOF, DISPLAY SUBSTRATE AND DISPLAY DEVICE”, which is incorporated here by reference in its entirety.

### TECHNICAL FIELD

The present disclosure relates to the technical field of display, more particularly, to a flexible array substrate and a preparation method thereof, a display substrate, and a display device.

### BACKGROUND

Flexible display devices have been increasingly applied in the fields of wearable devices, electronic paper, etc., due to their characteristics such as thinness, lightness, portability and flexibility.

### SUMMARY

Some embodiments of the present disclosure provide a flexible array substrate, comprising a display area and a non-display area, and the non-display area comprises a bending area adjacent to the display area. The bending area comprises a plurality of signal lines and a plurality of auxiliary lines on the base substrate, and the plurality of auxiliary lines are on a side of the plurality of signal lines away from the base substrate. An insulating layer is disposed between the plurality of auxiliary lines and the plurality of signal lines, and the insulating layer is provided with a concave section group formed by a plurality of concave sections which are arranged along an extension direction of the signal line in a region where the bending area overlaps any one of at least some signal lines of the plurality of signal lines, and each of the auxiliary lines covers at least one of concave section groups.

In some embodiments, one of the plurality of concave sections is a blind hole, and/or a through hole.

In some embodiments, the insulating layer is mainly composed of an organic insulating material.

In some embodiments, the plurality of auxiliary lines are mainly composed of a conductive material.

In some embodiments, the plurality of auxiliary lines are made of a same material as the plurality of signal lines.

In some embodiments, the insulating layer is provided with a concave section group in each region where the insulating layer overlaps each of the plurality of signal lines.

In some embodiments, one of the plurality of auxiliary lines covers one of the concave section groups, or one of the auxiliary lines covers a plurality of the concave section groups, and at most one of the plurality of concave section groups comprises a through hole.

In some embodiments, one of the auxiliary lines covers a plurality of the concave section groups, and only one of a plurality of the concave section groups comprises a through hole.

In some embodiments, one of the plurality of signal lines is at least one of a data line, a gate line, and a common electrode line.

In some embodiments, the plurality of auxiliary lines are in a same layer as and made of a same material as the pixel electrode in the flexible array substrate.

In some embodiments, the flexible array substrate further comprises a film layer on a side of the plurality of signal lines close to the base substrate. The film layer is provided with a groove in the bending area along a direction substantially perpendicular to an extension direction of the plurality of signal lines in the bending area. The groove is filled with an insulator comprising an organic insulating material, and a surface of the insulator on a side away from the base substrate is aligned with a surface of the film layer in contact with the plurality of signal lines.

Some embodiments of the present disclosure provide a method for preparing a flexible array substrate, and the flexible array substrate comprises a display area and a non-display area. The method for preparing a flexible array substrate comprises: forming a plurality of signal lines in the bending area adjacent to the display area in the non-display area of the base substrate. An insulating layer is formed on the base substrate on which the plurality of signal lines are formed; the insulating layer is formed with a concave section group in a region where the bending area overlaps any one of at least some signal lines of the plurality of signal lines. Each concave section group comprises a plurality of concave sections arranged along an extension direction of a corresponding one of the signal lines. A plurality of auxiliary lines are formed on the base substrate on which the insulating layer is formed and in the bending area. Each of the auxiliary lines covers at least one of the concave section groups.

In some embodiments, at least one of the concave sections in each of the concave section groups is formed by a through hole.

In some embodiments, forming a plurality of auxiliary lines on the base substrate on which the insulating layer is formed and in the bending area comprises: the plurality of auxiliary lines are formed on the base substrate on which the insulating layer is formed, and are formed by using a conductive material in the bending area.

Some embodiments of the present disclosure provide a display substrate, comprising the aforementioned flexible array substrate.

Some embodiments of the present disclosure provide a display device, comprising the aforementioned display substrate.

### BRIEF DESCRIPTION OF THE DRAWINGS

In order to describe technical solutions in embodiments of the present disclosure or in the related art more clearly, the accompanying drawings to be used in the description of embodiments or in the related art will be introduced briefly. Obviously, the accompanying drawings to be described below are merely some embodiments of the present disclosure, and a person of ordinary skill in the art can obtain other drawings according to these drawings without paying any creative effort.

FIG. 1 is a schematic structural diagram of a flexible array substrate provided in the related art;

FIG. 2 is a schematic structural diagram of a flexible array substrate provided in some embodiments of the present disclosure;

FIG. 3 is a sectional structural diagram of FIG. 2 along an O-O′ line;

FIG. 4 is a schematic structural diagram of another flexible array substrate provided in some embodiments of the present disclosure;

FIG. 5 is a schematic structural diagram of a further flexible array substrate provided in some embodiments of the present disclosure;

FIG. 6 is a schematic structural diagram of yet another flexible array substrate provided in some embodiments of the present disclosure;

FIG. 7 is a schematic structural diagram of yet still another flexible array substrate provided in some embodiments of the present disclosure;

FIG. 8 is a flow diagram of a method for preparing a flexible array substrate provided in some embodiments of the present disclosure.

### DETAILED DESCRIPTION

The technical solutions in the embodiments of the present disclosure will be described clearly and completely with reference to the accompanying drawings. Obviously, the described embodiments are merely some but not all of embodiments of the present disclosure. All other embodiments made on the basis of the embodiments of the present disclosure by a person of ordinary skill in the art without paying any creative effort shall be included in the protection scope of the present disclosure.

For a flexible display device, a frameless effect with a screen occupation ratio of more than 90% or a narrow frame can be achieved by bending the flexible display device in the bending area.

As shown in FIG. 1, a flexible display device includes a non-display area 10 and a display area 20, and a bending area 01 (Bonding Area) is provided at a position where the non-display area 10 is close to the display area 20. The non-display area 10 is bent toward the back (that is, non-display side, direction F in FIG. 1) of the flexible display device along the bending area 01, such that the flexible display device presents a narrow frame effect or even a frameless effect.

However, since a large number of signal lines are arranged in the non-display area 10, the signal lines are easily broken during the bending process, which leads to a decrease in the conformity rate of the display device.

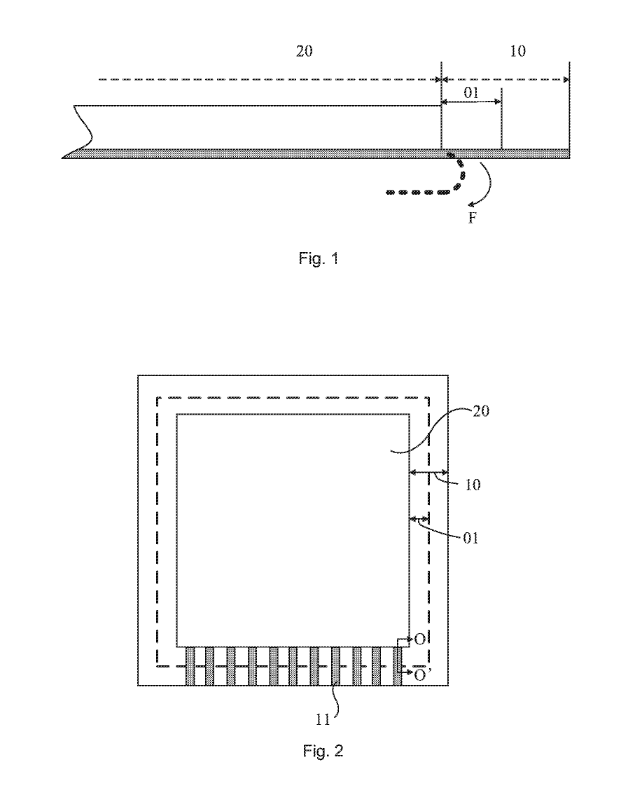

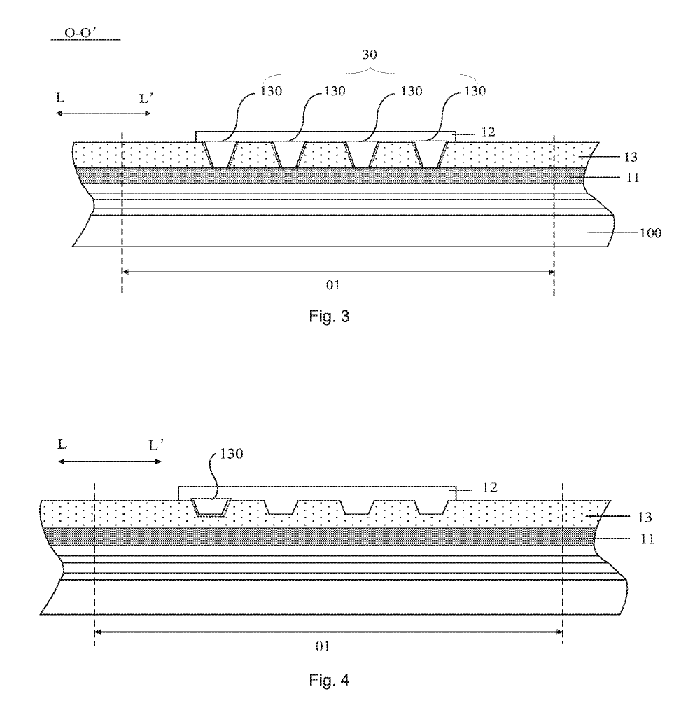

Based on this, some embodiments of the present disclosure provide a flexible display device, as shown in FIG. 2, including a non-display area 10 and a display area 20. The non-display area 10 includes a bending area 01 adjacent to the display area 20, and a plurality of signal lines 11 on the base substrate 100 (which is shown in FIG. 3) are included in the bending area 01.

It should be understood by those skilled in the art that the signal line 11 is not merely located in the bending area 01. In some embodiments of the present disclosure, the signal lines 11 extend from the display area 20 of the flexible array substrate to the bending area 01 and passes through the bending area 01. A signal line 11 is one or more selected from a gate line (in some embodiments, a portion of the gate line that extends to the non-display area 10 is called a gate line lead), a data line (in some embodiments, a portion of the data line that extends to the non-display area 10 is called a data line lead), and a common electrode line (in some embodiments, a portion of the common electrode line that extends to the non-display area 10 is called a common electrode line lead). In some embodiments, the signal line 11 further includes other signal lines that extend from the display area 20 and pass through the bending area 01.

As shown in FIG. 3 (a sectional diagram of FIG. 2 along an O-O′ line), the bending area 01 of the flexible array substrate further includes a plurality of auxiliary lines 12 on the base substrate 100, and the plurality of auxiliary lines 12 are on a side of the plurality of signal lines 11 away from the base substrate 100. An insulating layer 13 is disposed between the plurality of auxiliary lines 12 and the plurality of signal lines 11. In some embodiments, the insulating layer 13 is a planarization layer (PLN). In some embodiments, the insulating layer 13 is made from an organic insulating material. The organic insulating material is, for example, a resin. In some embodiments, the insulating layer 13 has a one-layer structure or a multi-layer structure.

On this basis, as shown in FIG. 3, the insulating layer 13 is provided with a concave section group 30 formed by a plurality of concave sections 130 arranged along an extension direction L-L′ of the signal line 11 in a region where the bending area 01 overlaps any one of at least some signal lines 11 of the plurality of signal lines 11, and each of auxiliary lines 12 covers at least one concave section group 30.

It should be understood here that one concave section group 30 corresponds to one signal line 11.

It should be noted that for any one of at least some signal lines 11 of the plurality of signal lines 11, a region of the insulating layer 13 where the bending area 01 overlaps the signal line 11 refers to an overlapping area where the projection of the insulating layer 13 of the bending area 01 on the base substrate 100 overlaps the projection of the signal line 11 on the base substrate 100.

Each of the concave section groups 30 includes two or more concave sections 130 along the extension direction L-L′ of each of the signal lines 11. As shown in FIG. 3, the concave section group 30 includes four concave sections 130. Of course, FIG. 3 only illustrates schematically for the example that the concave section group 30 includes four concave sections 130, and the embodiments of the present disclosure do not limit the number of the concave sections 130 in the concave section group 30, which can be set according to actual needs. In addition, some embodiments of the present disclosure do not limit the shape and the size of the concave section 130. In some embodiments of the present disclosure, the concave section 130 is circular, square, or the like.

For any one of at least some signal lines 11 of the plurality of signal lines 11, the number of the concave sections 130 arranged in a direction substantially perpendicular to the extension direction L-L′ of the signal line 11 in a region where the insulating layer 13 overlaps the signal line 11 is not limited. It should be noted that the range of angle indicated by the term “substantially perpendicular” in some embodiments of the present disclosure is 90°±10°.

In some embodiments of the present disclosure, for any one of at least some signal lines 11 of the plurality of signal lines 11, a plurality of (at least two) concave sections 130 are arranged along the direction substantially perpendicular to the extension direction L-L′ of the signal line 11 in a region where the insulating layer 13 overlaps the signal line 11. That is, for any one of at least some signal lines 11 of the plurality of signal lines 11, the concave sections 130 in the concave section group 30 form a multi-row structure in the region where the insulating layer 13 overlaps the signal line 11 along the direction substantially perpendicular to the extension direction of the signal line 11.

In some embodiments of the present disclosure, for any one of at least some signal lines 11 of the plurality of signal lines 11, the insulating layer 13 is only provided with one concave section along the direction substantially perpendicular to the extension direction L-L′ of the signal line 11 in a region where the insulating layer 13 overlaps the signal line 11 (referring to FIG. 6). That is, for any one of at least some signal lines 11 of the plurality of signal lines 11, the concave sections 130 in the concave section group 30 form a single-row structure in the region where the insulating layer 13 overlaps the signal line 11 along the direction substantially perpendicular to the extension direction of the signal line 11.

For the flexible array substrate, the base substrate 100 is made from a flexible bendable material. In some embodiments, the base substrate 100 is made by combining an upper and a lower polyimide (Pl) layers with an intermediate inorganic thin film layer disposed therebetween. In some embodiments, the base substrate 100 is made from a single Pl layer or a plurality of Pl layers.

It is not limited for the signal line 11 and the auxiliary line 12 to be directly disposed on the base substrate 100. In some embodiments, before the signal line 11 and the auxiliary line 12 are arranged, the base substrate 100 is provided with other film layers, such as a barrier layer and a buffer layer and so on. In some embodiments, according to a structure (for example, a type of a thin film transistor (TFT), one type of a thin film transistor corresponding to one structure) in the display area 20, a gate insulating layer (GI) (for a single-gate TFT, there is one gate insulating layer, and for a double-gate TFT, there are two gate insulating layers), an interlayer dielectric layer (ILD), and the like are further disposed on the base substrate 100.

In a flexible array substrate provided in some embodiments of the present disclosure, the insulating layer 13 is provided with a concave section group 30 formed by a plurality of concave sections 130 which are arranged along the extension direction of the signal line 11 in a region where the bending area 01 overlaps any one of at least some signal lines 11 of the plurality of signal lines 11, and each of the auxiliary lines 12 covers at least one of the concave section groups 30. Therefore, when the flexible array substrate is bent toward its back (i.e., the non-display side) in the bending area 01, the bending stress can be effectively dispersed along an arrangement direction of the plurality of concave sections 130 in the concave section group 30 corresponding to the auxiliary line 12, on the basis of the existence of the auxiliary line 12 corresponding to the signal line 11. Thus, the bending stress on the signal line 11 is reduced, which lowers the probability that the signal line 11 is broken due to bending, and improves the conformity rate of the flexible array substrate.

In some embodiments, the materials constituting the auxiliary lines 12 are not limited.

In some embodiments, the materials of the auxiliary lines 12 are non-conductive materials.

In some embodiments, the materials of the auxiliary lines 12 are conductive materials. On this basis, in order to avoid adding additional pattern-composition processes or additional equipments for realizing theses processes, the auxiliary lines 12 are formed in a same pattern-composition process as other conductive patterns of the display area 20, or are formed by using same materials and equipments as the other conductive patterns, by taking the actual preparation process of the flexible array substrate in consideration.

In some embodiments, the auxiliary line 12 and a pixel electrode in the display area 20 are formed in a single pattern-composition process. That is, the auxiliary line 12 is in the same layer as the pixel electrode and is made of the same material as the pixel electrode. The auxiliary line 12 is made of, for example, one or more of transparent conductive materials such as indium tin oxide (ITO), indium gallium zinc oxide (IGZO), and indium zinc oxide (IZO). In some embodiments, the auxiliary line 12 and a gate line (when a top gate structure is employed in a TFT in the display area) in the display area 20 are formed in a single pattern-composition process.

In some embodiments, the auxiliary line 12 and the signal line 11 (for example, a data line) are made of a same material. For example, both the auxiliary line 12 and the signal line 11 are made of a composite material of titanium/aluminum/titanium (Ti/Al/Ti), so that they can be prepared by using the existing equipments and materials.

An exemplary arrangement of the concave sections 130 in the concave section group 30 will be further described below.

In some embodiments, the plurality of concave sections 130 in the concave section group 30 are evenly scattered along an extension direction L-L′ of the signal line 11 to ensure that the auxiliary line 12 can evenly disperse the bending stress by the aid of the concave section group 30 at the time of bending the bending area 01.

On this basis, when the flexible array substrate is bent along the bending area 01, since the bending stresses on different regions are different, in some embodiments of the present disclosure, the concave section group 30 and the auxiliary line 12 covering the concave section group 30 are disposed in a region where the bending stress is large, and not a concave section group 30 or an auxiliary line 12 is disposed in a region where the bending stress is small. Of course, in order to ensure that the stresses of all signal lines 11 of the entire bending area 01 can be dispersed and the signal lines 11 can be effectively prevented from being broken, in some embodiments of the present disclosure, the insulating layer 13 is provided with a concave section group 30 for any signal line 11 in the region where the bending area 01 overlaps the signal line 11, and each of the concave section groups 30 is covered with an auxiliary line 12.

In some embodiments, a spacing distance (along the extension direction L-L′ of the signal line) between adjacent two of the concave sections 130 in the concave section group 30 is not limited, which can be set according to actual needs.

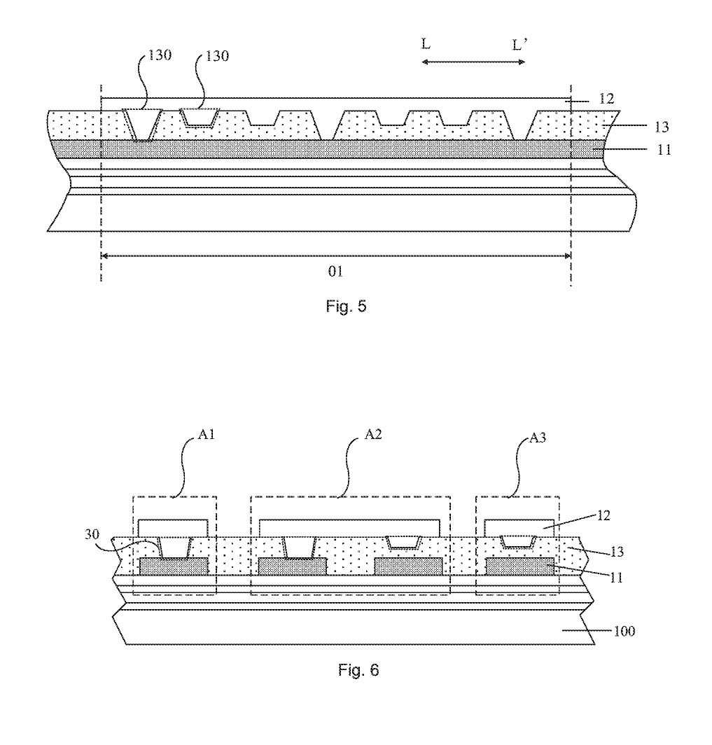

In some embodiments, as shown in FIG. 3 or FIG. 4, a length of the concave section group 30 along the extension direction L-L′ of the signal line is smaller than a length of the bending area 01 along the same direction. In some embodiments, as shown in FIG. 5, the length of the concave section group 30 is equal to or approximately equal to the length of the bending area 01, in which case the bending stress can be dispersed to the insulation layer to a greater extent through the concave section 130.

In some embodiments, as shown in FIG. 3, the concave section 130 in the concave section group 30 is a through hole. That is, the concave section 130 penetrates the whole insulating layer 13, and the auxiliary line 12 can be connected to the signal line 11 through the concave section 130 in the concave section group 30 when the auxiliary line 12 covers the concave section group 30.

In some embodiments, as shown in FIG. 4, the concave section 130 in the concave section group 30 is a blind hole. That is, the concave section 130 does not penetrate the whole insulating layer 13, and the auxiliary line 12 and the corresponding signal line 11 are two independent parts (insulated) when the auxiliary line 12 covers the concave section group 30.

In some embodiments, as shown in FIG. 5, the concave sections 130 in the concave section group 30 include both a blind hole and a through hole. In this case, the blind hole and the through hole are arranged according to actual needs. For example, depending on the difference of bending stress on different positions of the flexible array substrate, the blind hole and the through hole are arranged differently at the different positions. In some embodiments, a plurality of through holes arranged continuously are disposed at a position where local bending stress is large, and a plurality of blind holes arranged continuously are disposed at a position where local bending stress is small. In some embodiments, the blind hole and the through hole are arranged in a regular rule. For example, as shown in FIG. 5, a through hole is provided for every two blind holes.

It should be understood here that in a case where the concave sections 130 in the concave section group 30 include a through hole (referring to FIGS. 3 and 5), the auxiliary line 12 is equivalent to a resistor connected in parallel with a signal line 11, if the auxiliary line 12 is made of a conductive material. Thereby, when the bending stress on the signal line 11 is dispersed, the overall resistance of the signal line 11 can be reduced, so that a display device including the flexible array substrate can consume less power while achieving a same display effect. In this case, normal transmission of signals can be ensured as long as one of the auxiliary line 12 and the signal line 11 is not broken, thereby improving the conformity rate.

Based on this, in some embodiments, at least one of the concave sections 130 in each of the concave section groups 30 is a through hole, and the auxiliary line 12 is made from a conductive material. The conductive material is, for example, a metal, a transparent conductive material, or the like. Of course, in order to avoid adding additional pattern-composition processes or equipments, in some embodiments, the auxiliary lines 12 are formed in a same pattern-composition process as other conductive patterns of the display area 20, or are formed using the same process materials and equipments as the other conductive patterns. The following description is made by taking the auxiliary line 12 being made from a conductive material as an example.

It should be noted that, for any one of the auxiliary lines 12, the number of the concave section groups 30 covered thereby is not limited.

In some embodiments, an auxiliary line 12 covers one concave section group 30, as shown in sections A1 and A3 of FIG. 6.

The concave section group 30 includes a plurality of concave sections 130 arranged along the extension direction of the corresponding signal line 11, and each of the auxiliary lines 12 covers one concave section group 30. Therefore, the extension direction of an auxiliary line 12 that covers any one of the concave section groups 30 is the same as the extension direction L-L′ of the signal line 11 corresponding to the concave section group 30. That is, the extension direction of each of the auxiliary lines 12 is the same as the extension direction L-L′ of the signal line 11 corresponding to the auxiliary line 12.

In some embodiments, as shown in section A2 of FIG. 6, an auxiliary line 12 covers a plurality of (at least two) concave section groups 30. In the case where one auxiliary line 12 covers a plurality of (at least two) concave section groups 30, in order to ensure normal signal transmission of the signal line 11, it should be ensured that at most one of the plurality of concave section groups 30 include a through hole. In some embodiments, in a case where an auxiliary line 12 covers a plurality of concave section groups 30, only one of the plurality of concave section groups 30 include a through hole. That is, in the case of this setting, the auxiliary line 12 is connected to one signal line 11 merely through one concave section group with one through hole among the plurality of concave section groups 30, and other concave section groups 30 among the plurality of concave section groups 30 should be realized as blind holes. This ensures that the signal lines 11 corresponding to the plurality of concave section groups 30 are insulated from each other, and thereby ensures that a display device including the flexible array substrate can display normally.

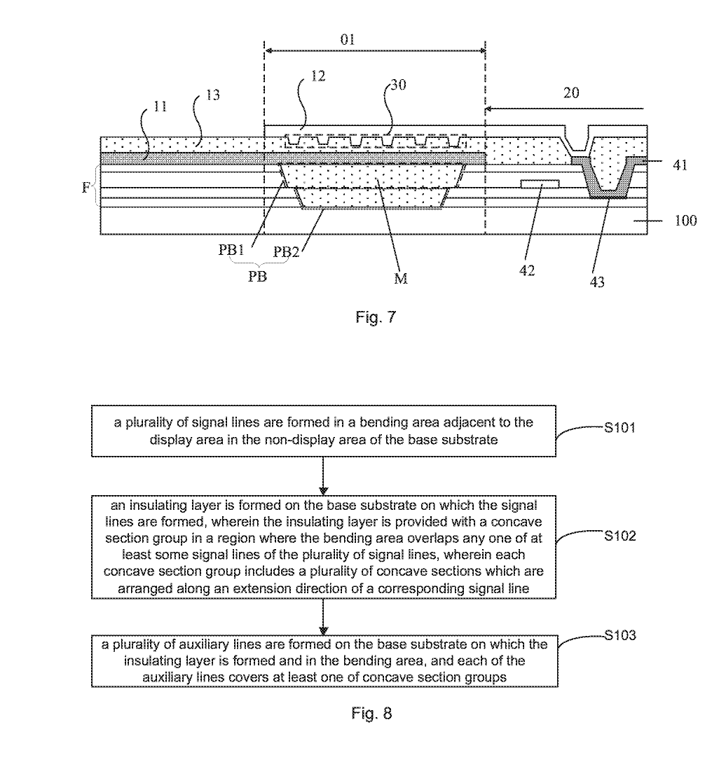

It should also be understood here that, for the section A3 in FIG. 6, in a case where all the concave sections 130 in the concave section group 30 (for example, as shown in FIG. 7) are blind holes, the auxiliary line 12 at the corresponding position is not electrically connected to the signal line 11. Based on this, in some embodiments, the signal line 11 is a data line; the auxiliary line 12 is directly connected to a source electrode 41 of a thin film transistor in the display area 20, and it transmits signals separately as an independent signal transmission line. Thus, the flexible array substrate can have sufficient space and is easier to arrange the signal lines 11 and the flexible array substrate is more applicable to a high-resolution display device.

It should be noted here that the signal line 11 shown in FIG. 7 is also connected to source electrodes 41 of other thin film transistors in the display area 20, which is not shown in FIG. 7. In the display area 20 there is also provided with a drain electrode, a gate electrode 42, a gate line, an active layer 43 and the like, and it is unnecessary to go into details here.

On this basis, referring to FIG. 7, the flexible array substrate is provided with another film layer F on a side of the signal line 11 close to the base substrate 100, and the film layer F is configured to be a single layer or multiple layers. In some embodiments, the film layer F includes a barrier layer, a buffer layer, a gate insulating layer (GI), an interlayer dielectric layer (ILD), and the like between the signal line 11 and the base substrate 100, and of course, it is not limited to this.

The film layer on a side of the signal line 11 close to the base substrate 100 may break due to bending, and the break may be transmitted to the signal line 11, causing the signal line 11 to break. In order to avoid this circumstance, as shown in FIG. 7, in some embodiments, a groove PB along a direction substantially perpendicular to an extension direction of the signal line 11 in the film layer at a side of the signal line 11 close to the base substrate 100 is disposed in the bending area 01, and the groove PB is filled with an insulator M including an organic insulating material. A surface of the insulator M on a side away from the base substrate 100 is aligned with a surface of the film layer F in contact with the signal line 11.

In this way, a side of the signal line 11 in the bending area 01 close to the base substrate 100 is in direct contact with the insulator M including the organic insulating material. Since the organic insulating material has a large flexibility and is not easy to break, the signal line 11 will not break due to break of the film layer F located under the signal line 11 at the time of bending.

On this basis, in order to make the bending area 01 easy to bend, a portion of the film layer F, which is on a side of the signal line 11 close to the base substrate 100, in a region where the groove PB is to be formed is completely removed through an etching process before the groove PB is arranged. There are usually many layers to be included in the film layer F, which is on the side of the signal line 11 close to the base substrate 100, and therefore the film layer F has a large thickness. On this basis, excessive etching may be caused when removing the portion of the film layer F in a region where the groove PB is to be formed in a single etching process; consequently, the photoresist (light-sensitive lacquer) layer covering other positions of the flexible array substrate may be seriously damaged to cause an adverse effect. Therefore, in order to avoid this circumstance, the first groove PB1 and the second groove PB2 are respectively formed in two etching processes (forming the photoresist layer twice) in actual manufacturing.

In addition, those skilled in the art should understand that in some embodiments of the present disclosure, the flexible array substrate is applied to an OLED (Organic Light Emitting Diode) display screen. In some embodiments of the present disclosure, the flexible array substrate is applied to an LCD (Liquid Crystal Display) display screen comprising a flexible base substrate.

Some embodiments of the present disclosure provide a display substrate including the flexible array substrate as described above. It has the same beneficial effects as the flexible array substrate. Since the aforementioned embodiments have described the structure and beneficial effects of the flexible array substrate in detail, it is unnecessary to go into details here.

Some embodiments of the present disclosure provide a display device including the display substrate as described above. Since the display substrate includes the flexible array substrate as described above, the display device has the same beneficial effects as the flexible array substrate. Since the aforementioned embodiments have described the structure and beneficial effects of the flexible array substrate in detail, it is unnecessary to go into details here.

In some embodiments of the present disclosure, the display device includes an organic light emitting diode display panel. The display panel is applied, for example, to any product or component having a display function, such as a displayer, a television, a digital photo frame, a mobile phone, and a tablet computer.

Some embodiments of the present disclosure provide a method for preparing a flexible array substrate, and the flexible array substrate includes a display area and a non-display area. As shown in FIG. 8, the preparation method comprises S101-S103.

S101, a plurality of signal lines are formed in a bending area adjacent to the display area in the non-display area of the base substrate.

In some embodiments, the signal line is one or more of a gate line (lead), a data line (lead), and a common electrode line (lead), but is not limited to this.

In addition, it should be understood by those skilled in the art that the signal line is not merely located in the bending area, and it extends from the display area of the flexible array substrate to the bending area and passes through the bending area.

S102, an insulating layer is formed on the base substrate on which the signal lines are formed. The insulating layer is provided with a concave section group in a region where the bending area overlaps any one of at least some signal lines of the plurality of signal lines, wherein each of the concave section groups includes a plurality of concave sections which are arranged along an extension direction of the signal line.

In some embodiments, at least one of the concave sections in each of the concave section groups is a through hole. In some embodiments, all the concave sections in each of the concave section groups are through holes. Thereby, the bending stress can be effectively dispersed along an arrangement direction of the plurality of concave sections.

In some embodiments, the insulating layer being formed includes: forming an insulating layer mainly composed of an organic insulating material on a base substrate on which a signal line is formed, wherein a concave section group in a region where the insulating layer overlaps each signal line (referring to FIG. 3) is formed the insulating layer, and the concave section group includes a plurality of through holes arranged along an extension direction of the signal line.

S103, a plurality of auxiliary lines are formed in the bending area and on the base substrate on which the insulating layer is formed, and each of the auxiliary lines covers at least one concave section group.

In some embodiments, “a plurality of auxiliary lines are formed in the bending area and on the base substrate on which the insulating layer is formed” in S103 includes: a plurality of auxiliary lines being formed in the bending area and on the base substrate on which the insulating layer is formed by using conductive materials.

It should be understood here that a large number of other conductive patterns will be made in the display area during the manufacturing process of the flexible array substrate. Thus, on one hand, in a case where the auxiliary line is made of a conductive material, the auxiliary line is formed in a same manufacturing process or using the same materials and equipments as other conductive patterns of the display area, avoiding additional manufacturing processes or equipments. On the other hand, in a case where a through hole is included in the concave section group, the overall resistance of the signal line can be reduced while the bending stress on the signal line is dispersed, and in a case where one of the auxiliary line and the signal line is not broken, normal signal transmission can still be ensured.

Of course, generally after S103, there are other manufacturing steps for manufacturing the flexible array substrate. For example, a PLN is formed on the base substrate on which the auxiliary lines are formed, and it is unnecessary to go into details here.

Since the insulating layer is provided with a concave section group formed by a plurality of concave sections which are arranged along an extension direction of the signal lines in a region where the bending area overlaps any one of at least some signal lines of the plurality of signal lines, and each of the auxiliary lines covers at least one of the concave section groups. Therefore, when the flexible array substrate is bent toward the back thereof (that is, the non-display side) in the bending area, the bending stress can be effectively dispersed along the arrangement direction of the plurality of concave sections in the concave section group corresponding to the auxiliary line by the aid of the auxiliary line corresponding to the signal line. Consequently, the bending stress on the signal line is reduced, which lowers the probability that the signal line breaks due to bending, and improves the conformity rate of the flexible array substrate.

For the related arrangements and beneficial effects in the preparation method of the flexible array substrate, reference can be made to the related embodiments of the flexible array substrate, and it is unnecessary to go into details here.

The above embodiments are merely specific embodiments of the present disclosure, but the protection scope of the present disclosure is not limited thereto. For those skilled in the art, various changes and modifications can be made therein without departing from the spirit and essence of the disclosure, which are also considered to be within the scope of the disclosure. Therefore, the protection scope of the present disclosure shall be determined by the protection scope of the claims.

What is claimed is:

1. A flexible array substrate, comprising a display area and a non-display area, wherein the non-display area comprises a bending area adjacent to the display area;
the bending area comprises a plurality of signal lines and a plurality of auxiliary lines on a base substrate, and the plurality of auxiliary lines is on a side of the plurality of signal lines away from the base substrate;
an insulating layer is disposed between the plurality of auxiliary lines and the plurality of signal lines, and the insulating layer is provided with a concave section group formed by a plurality of concave sections which are arranged along an extension direction of the signal line in a region where the bending area overlaps any one of at least some signal lines of the plurality of signal lines, and each of the auxiliary lines covers at least one of concave section groups.

2. The flexible array substrate according to claim 1, wherein one of the plurality of concave sections is a blind hole, and/or a through hole.

3. The flexible array substrate according to claim 1, wherein the insulating layer is mainly composed of an organic insulating material.

4. The flexible array substrate according to claim 1, wherein the plurality of auxiliary lines are mainly composed of a conductive material.

5. The flexible array substrate according to claim 4, wherein the plurality of auxiliary lines are made from a same material as the plurality of signal lines.

6. The flexible array substrate according to claim 1, wherein the insulating layer is provided with a concave section group in each region where the insulating layer overlaps each of the plurality of signal lines.

7. The flexible array substrate according to claim 1, wherein
one of the plurality of auxiliary lines covers one of the concave section groups;
or, one of the auxiliary lines covers a plurality of the concave section groups, and at most one of the plurality of concave section groups comprises a through hole.

8. The flexible array substrate according to claim 7, wherein one of the auxiliary lines covers a plurality of the concave section groups, and only one of the plurality of concave section groups comprises a through hole.

9. The flexible array substrate according to claim 1, wherein one of the plurality of signal lines is at least one of a data line, a gate line, and a common electrode line.

10. The flexible array substrate according to claim 1, wherein the plurality of auxiliary lines are in a same layer as and made of a same material as pixel electrodes in the flexible array substrate.

11. The flexible array substrate according to claim 1, further comprising a film layer on a side of the plurality of signal lines close to the base substrate;
the film layer is provided with a groove along a direction substantially perpendicular to an extension direction of the plurality of signal lines in the bending area; the groove is filled with an insulator comprising an organic insulating material, and a surface of the insulator on a side away from the base substrate is aligned with a surface of the film layer in contact with the plurality of signal lines.

12. A method for preparing a flexible array substrate, the flexible array substrate comprising a display area and a non-display area, wherein the method for preparing a flexible array substrate comprises:
forming a plurality of signal lines in a bending area adjacent to the display area in the non-display area of the base substrate;
forming an insulating layer on the base substrate on which the plurality of signal lines are formed; wherein the insulating layer is formed with a concave section group in a region where the bending area overlaps any one of at least some signal lines of the plurality of signal lines; each concave section group comprises a plurality of concave sections arranged along an extension direction of a corresponding signal line;
forming a plurality of auxiliary lines on the base substrate on which the insulating layer is formed and in the bending area, each of the auxiliary lines covers at least one of concave section groups.

13. The method for preparing a flexible array substrate according to claim 12, wherein at least one of the concave sections in each of the concave section groups is formed by a through hole.

14. The method for preparing a flexible array substrate according to claim 12, wherein forming a plurality of auxiliary lines on the base substrate on which the insulating layer is formed and in the bending area comprises:
forming the plurality of auxiliary lines on the base substrate on which the insulating layer is formed and in the bending area using a conductive material.

15. A display substrate, comprising the flexible array substrate according to claim 1.

16. A display device, comprising the display substrate according to claim 15.
